(19) United States
(12) Patent Application Publication
(10) Pub. No.: US 2025/0044345 A1
(43) Pub. Date: Feb. 6, 2025

(54) UNIVERSAL DETECTION DEVICE AND METHOD FOR HIGH SPEED DIGITAL INTERFACE OF INTEGRATED CIRCUIT

(71) Applicant: MACROTEST SEMICONDUCTOR TECHNOLOGY CO., LTD, Nanjing (CN)

(72) Inventors: Guoliang MAO, Nanjing (CN); Quanren Ll, Nanjing (CN)

(21) Appl. No.: 18/714,518

(22) PCT Filed: Mar. 15, 2023
(86) PCT No.: PCT/CN2023/081509

§ 371 Date: May 29, 2024

(30) Foreign Application Priority Data
Apr. 29, 2022 (CN) 202210464146.6

(51) Int. Cl. G01R 31/28; G01R 31/319

(52) U.S. Cl. CPC G01R 31/2834; G01R 31/2884; G01R 31/31908

(57) ABSTRACT

The present disclosure discloses a universal detection device and method for a high speed digital interface of an integrated circuit, including a mid speed digital test channel board and a high speed digital test channel board, wherein the mid speed digital test channel board includes a test processor and a mid speed test channel unit; a high speed test channel board interface is arranged on a mid speed test channel group; the high speed digital test channel board includes a test processor board interface, a field programmable gate array (FPGA) code config generator, a high speed test channel driver FPGA capable of configuring an interface protocol, a high speed test channel unit, and a configurable test data processor; and the test processor board interface is connected to a high speed test channel board interface of the mid speed test channel group. The present disclosure can meet a mid speed test requirement of a general IO and meet testing of high speed interfaces. Both high flexibility of an FPGA scheme and low cost of a mid-end automatic test equipment (ATE) machine can be achieved.

### TECHNICAL FIELD

The present disclosure relates to a universal detection device and method for a high speed digital interface of an integrated circuit, and belongs to a chip detection technology.

### BACKGROUND

Due to the increasing use of high speed digital interfaces in the design of modern digital integrated circuits, such as a Mobile Industry Processor Interface (MIPI), a High-Definition Multimedia Interface (HDMI), Serdes, DDR, a Universal Serial Bus (USB), and a Peripheral Component Interface Express (PCle), this type of digital interface has a data transmission rate ranging from hundreds of Mbps to several Gbps, and physical interface types include LVCMOS, LVDS, to LVPECL or CML, or the like. In Automatic Test Equipment (ATE), it is of great challenge to detect this type of signal. The first challenge is the ultra-high testing frequency. The data transmission speed from hundreds of Mbps to Gbps often causes an interface level to change from hundreds of MHz to GHz. If a Timing Generators (TG) of the traditional ATE is used for testing, the equipment cost is too high (basically, only top-end ATE has this function, or a large number of test channels need to be sacrificed for a higher test data rate). The second challenge is a complex interface timing and protocol. For example, in terms of MIPI or PCle, this type of interface has a complete set of complex transmitting and receiving protocol, and has a very strict timing requirement. A timing error is at the ps level. There are also asynchronous concurrent testing requirements for interfaces such as DDR. For implementation in a Pattern Generator (PG) of the traditional ATE, complex command set supporting is required, and the PG itself needs to be very fast. A pattern may be very complex. This also has a high requirement for the test program development ability of testing personnel. The third challenge is diverse interface level modes, and a general ATE digital test IO interface cannot meet the requirement.

A first traditional solution is to use paired chips as receivers or transceivers. The ATE only needs to test outputs of the paired chips to indirectly complete testing of a Device Under Test (DUT). This testing method is the simplest. As the paired chips convert a high speed interface signal into a low speed signal, it greatly lowers the requirement on the ATE. However, this method cannot directly test the alternating current/direct current parameters of the DUT (because there is one paired chip between the ATE and the DUT). In addition, the ATE cannot directly apply a desired test signal to the DUT through a pattern, and can only indirectly generate a test timing through the paired chips. Due to the limitation caused by the functions of the paired chips, some parameters or functions of the DUT may not be fully tested.

A second traditional solution is to use a field programmable gate array (FPGA) to simulate paired chips as a receiver or a transceiver. Namely, an interface protocol and timing which are the same as those of the paired chips are designed in the FPGA for communication between a PG and a DUT. This method is similar to the first method. In addition to the issues of the first method, this method further has higher cost (the price of the FPGA is high), higher requirements on testing engineers (the testing engineers need to master the development, debugging, and other capabilities of the FPGA), and the like. This method has the advantage that the FPGA can be customized to solve the problem of incomplete testing of the DUT due to the limitation of the function of the paired chips in the first method.

A third traditional solution is to use a high-end ATE machine for direct testing (such as Edwan's Verigy 93K). A complex pattern program is developed using the high-end ATE machine, and test signals required by high speed testing are generated through digital channels. This method has advantages of flexible testing, high test coverage, convenient debugging, and the like, but has the disadvantage that the high-end ATE machine is often priced at hundreds of thousands of dollars to millions of dollars, causing high testing costs.

As can be seen from the above, the first traditional testing method has the problems of low testing coverage and low testing efficiency. The second traditional testing method has the problem of high testing and development complexity. The third traditional testing method has the problem of high testing costs. In summary, all the traditional testing schemes cannot achieve low testing costs, high flexibility in testing and development, low complexity in testing and development, and high coverage of testing. The various issues may increase the testing costs of design companies during integrated circuit (IC) testing.

### SUMMARY

Invention objective: To overcome the shortcomings in the prior art, the present disclosure provides a universal detection device and method for a high speed digital interface of an integrated circuit. In most integrated circuit testing processes, except that high speed interfaces require high speed digital signals, other IO interfaces have low requirements on digital signal rates (generally dozens of Mbps to hundreds of Mbps). To maintain high flexibility and testing integrity of high speed digital interface testing and testing and achieve low cost of testing, the present disclosure is achieved. The present disclosure integrates an IO interface of mid-end digital ATE machine with a high speed digital test function to form a combinable testing device. Namely, each mid speed test channel resource may also be switched to a dedicated high speed test channel according to a need. A high speed test channel is synchronized with a mid speed test channel through a pattern generator (PG). The high speed test channel is achieved through an FPGA and a front-end dedicated electronic pin. The device can meet a mid speed test requirement of a general IO and meet testing of high speed interfaces. Both high flexibility of an FPGA scheme and low cost of a mid-end automatic test equipment (ATE) machine can be achieved. To solve the development complexity of an FPGA scheme, corresponding interface template functions are designed, so that a test developer can complete development and debugging of a test program without mastering the FPGA.

Technical solutions: In order to achieve the above objectives, the present disclosure adopts the following technical solutions:

A universal detection device for a high speed digital interface of an integrated circuit includes a mid speed digital test channel board and a high speed digital test channel board, wherein

the mid speed digital test channel board includes a bus interface, a test processor, and a mid speed test channel unit; the bus interface is connected to the test processor and the mid speed test channel unit; the test processor is connected to the mid speed test channel unit; the mid speed test channel unit includes one or more groups of mid speed test channel groups; and a high speed test channel board interface is arranged on each group of mid speed test channel group;

the high speed digital test channel board includes a bus interface, a test processor board interface, an FPGA code config generator, a high speed test channel driver FPGA capable of configuring an interface protocol, a high speed test channel unit, and a configurable test data processor; the FPGA code config generator is configured to receive personal computer data to complete reconfiguration of the high speed test channel driver FPGA capable of configuring an interface protocol; the high speed test channel driver FPGA capable of configuring an interface protocol is configured to directly control the high speed test channel unit; the bus interface is connected to the FPGA code config generator, the high speed test channel driver FPGA capable of configuring an interface protocol, the high speed test channel unit, and the configurable test data processor respectively; the test processor board interface is connected to the high speed test channel board interface, the FPGA code config generator, the high speed test channel driver FPGA capable of configuring an interface protocol, the high speed test channel unit, and the configurable test data processor respectively; the high speed test channel driver FPGA capable of configuring an interface protocol is connected to the FPGA code config generator, the high speed test channel unit, and the configurable test data processor respectively; and the test processor board interface is connected to the high speed test channel board interface of the mid speed test channel unit to receive control and synchronization signals of the test processor.

Preferably, the test processor is configured to execute a pattern to generate a timing signal required by testing and a control signal required by a test channel, and provide the timing signal required by testing and the control signal required by a test channel to the mid speed test channel group, and is configured to generate a control signal required by the high speed digital test channel board to synchronize each high speed test channel driver FPGA capable of configuring an interface protocol on the high speed test channel unit with the test data processor.

Preferably, the mid speed test channel group includes an electronic pin, an input/output level converter, and a group of multiplexers; the electronic pin is configured to complete direct current testing of a device under test; the input/output level converter is configured to convert an input level and an output level; and the multiplexers are configured to output multiplexing signals.

Preferably, the high speed test channel unit includes one or more high speed test channels.

Preferably, the high speed test channels and the mid speed test channel groups are in one-to-one correspondence.

A universal detection method for a high speed digital interface of an integrated circuit includes the following steps:

step 1, writing a pattern, and configuring a high speed interface test protocol in integrated circuit ATE software;

step 2, downloading the pattern to the test processor;

step 3, downloading the high speed interface test protocol to the FPGA code config generator, and downloading a test data processing program to the configurable test data processor;

step 4, starting testing;

step 5, testing a direct current parameter of a device under test through the mid speed test channel unit; if the testing fails, executing step 4; if the testing succeeds, turning on the test processor;

step 6, driving, by the test processor, a mid speed test channel in the mid speed test channel unit to generate a test signal to the device under test, thus completing mid speed testing of the device under test; if the testing fails, executing step 4; if the testing succeeds, switching, by the test processor, the multiplexer to the high speed test channel unit;

step 7, turning on, by the test processor, the high speed test channel driver FPGA capable of configuring an interface protocol to cause the high speed test channel unit to generate a test signal to the device under test, thus completing high speed interface testing and data processing of the device under test; if the testing fails, executing step 4; and if the testing succeeds, ending the testing.

Preferably, the configurable test data processor performs real-time calculation on test data obtained by the high speed test channel driver FPGA capable of configuring an interface protocol, and synchronizes a test result to the test processor.

Compared with the prior art, the present disclosure has the following technical effects:

1. In the present disclosure, according to the design of the high speed channel test board, the high speed digital test channel and the mid speed digital test channel form mid speed and high speed matching, which can achieve lower testing costs than that of a high-end testing machine on the basis of meeting a requirement of a DUT for the high speed digital test channel to the largest extent.

2. In the present disclosure, due to the design of the configurable high speed channel driver FPGA, the high speed digital interface driver capability of the FPGA is obtained, and customized flexible configuration of a driver protocol is achieved. Meanwhile, since the driver protocol is developed for ATE customization, good test coverage can also be achieved.

3. A pre-configured driver protocol is edited, configured, and downloaded through ATE software, and the complexity of use of the FPGA can be solved. Test engineers can complete development of test programs of various high speed digital interface protocols without performing RTL development and debugging on the FPGA.

4. A configurable dedicated computing processor and memory structure is arranged in the independent high speed channel test board, so that hardware has asynchronous data processing and computing capabilities. Furthermore, by configuring a plurality of boards, a plurality of test sites can achieve concurrent testing, thereby reducing the occupation of system bus resources during testing and greatly improving the testing efficiency of a chip.

### BRIEF DESCRIPTION OF THE DRAWINGS

FIG. 1 is a schematic diagram of a mid speed digital test channel board.

FIG. 2 is a schematic diagram of a high speed digital test channel board.

FIG. 3 is a schematic structural diagram of a test processor.

FIG. 4 is a schematic diagram of implementation of testing.

FIG. 5 is a flowchart.

### DETAILED DESCRIPTION OF THE EMBODIMENTS

Based on the accompanying drawings and specific embodiments, the present disclosure will be further elaborated. It should be understood that these examples are only used to illustrate the present disclosure and not to limit the scope of the present disclosure. After reading the present disclosure, modifications to various equivalent forms of the present disclosure by those skilled in the art shall all fall within the scope defined by the claims attached to the present disclosure.

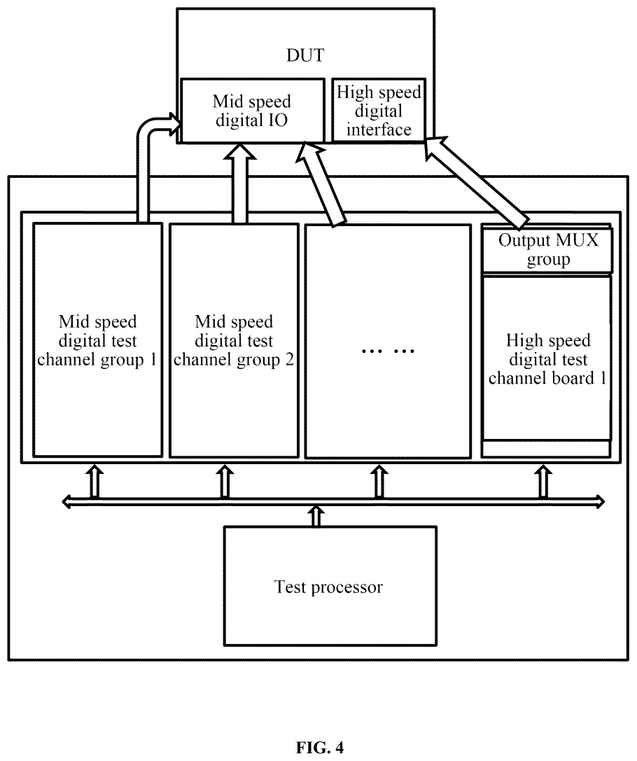

A universal detection device for a high speed digital interface of an integrated circuit is as shown in FIG. 4. Based on testing method II, this embodiment focuses on solving the problem of high testing development complexity and reducing the testing costs. To lower the testing development complexity, an automatic generation mechanism for an FPGA high speed interface protocol code is needed, so that testing engineers do not need to develop an FPGA. To reduce the testing costs, a high speed test channel needs to be configured to a low speed channel as needed to achieve the optimal cost-effectiveness. The universal detection device includes a mid speed digital test channel board 4 and a high speed digital test channel 10.

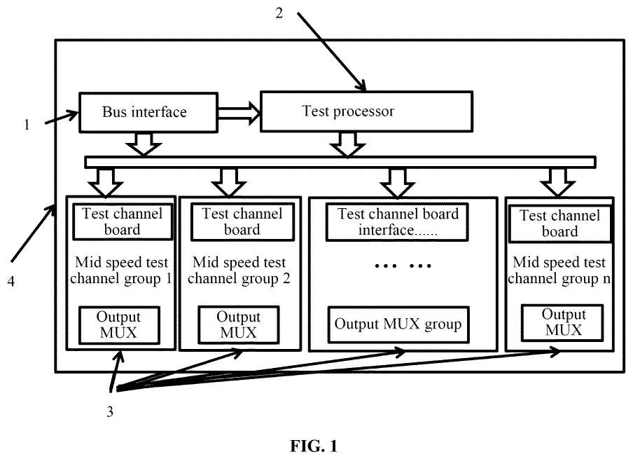

As shown in FIG. 1, the mid speed digital test channel board 4 includes a bus interface 1, a test processor 2, and a mid speed test channel unit 3; the bus interface 1 is connected to the test processor 2 and the mid speed test channel unit 3; the test processor 2 is connected to the mid speed test channel unit 3; the mid speed test channel unit 3 includes one or more groups of mid speed test channel groups; and a high speed test channel board interface is arranged on each group of mid speed test channel group; and

the mid speed digital test channel board (MSDTCB) 4 is configured to execute a pattern to complete test signal generation and testing of a mid speed IO of a device under test. Meanwhile, as a mother board, the mid speed digital test channel board and various HSTCB interfaces complete control and synchronization of various high speed digital test channel boards.

The bus interface (BI) 1 is configured for data transmission and control between a personal computer (PC) and the various components on the board, specifically for data transmission and control between the test processor 2, the mid speed test channel unit 3, and mid speed digital test channel board 4.

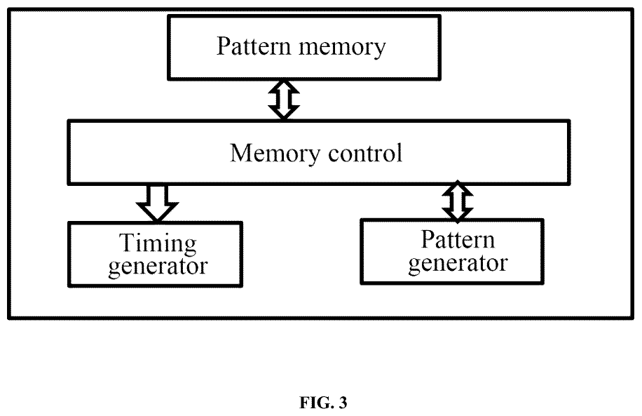

The test processor (TP) 2, as shown in FIG. 3, includes a pattern memory, a memory control, a timing generator, and a pattern generator. The memory control is connected to the pattern memory, the timing generator, and the pattern generator, respectively. The test processor 2 is configured to execute a pattern to generate a timing signal required by testing and a control signal required by a test channel, and provide the timing signal required by testing and the control signal required by a test channel to the mid speed test channel unit (3), and is configured to generate a control signal required by various test boards to synchronize various channel driver FPGAs on the test boards with test data processors on the test boards, namely, configured to generate a control signal required by the high speed digital test channel board 10 to synchronize each high speed test channel driver FPGA 7 capable of configuring an interface protocol on a high speed test channel unit 8 with a test data processor.

The mid speed test channel group is configured to generate a group of test signals (generally from dozens of Hz to hundreds of MHz) required by mid speed IO testing, is directly controlled by the test processor 2, and receives an output signal of the test processor 2 to generate a group of test signals required by mid speed IO testing. The mid speed test channel group includes a high speed test channel board (HSTCB) interface, an electronic pin (EP, which is composed of a PPMU, a driver, a comparator, and the like, to complete direct current testing of a DUT, perform input/output level conversion, and the like), and a group of multiplexers Mux. The electronic pin is configured to complete the direct current testing of a device under test; an input/output level converter is configured for input/output level conversion; and the multiplexers Mux are configured to output multiplexing signals.

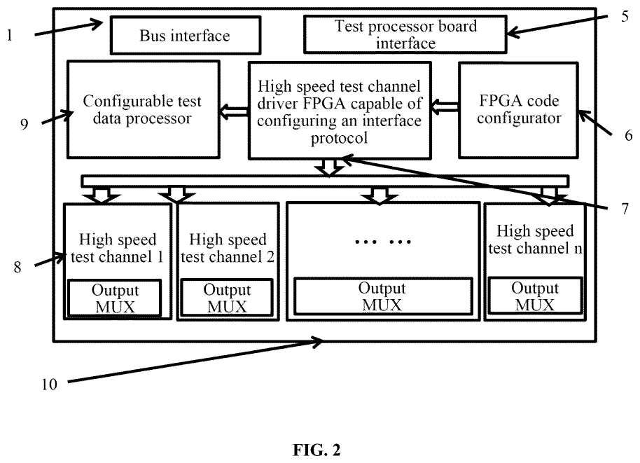

As shown in FIG. 2, the high speed digital test channel board 10 includes a bus interface 11, a test processor board interface 5, an FPGA code config generator 6, a high speed test channel driver FPGA 7 capable of configuring an interface protocol, a high speed test channel unit 8, and a configurable test data processor 9; the FPGA code config generator 6 is configured to receive upper computer data to complete reconfiguration of the high speed test channel driver FPGA 7 capable of configuring an interface protocol; the high speed test channel driver FPGA 7 capable of configuring an interface protocol is configured to directly control the high speed test channel unit 8; the bus interface 11 is connected to the FPGA code config generator 6, the high speed test channel driver FPGA 7 capable of configuring an interface protocol, the high speed test channel unit 8, and the configurable test data processor 9 respectively; the test processor board interface 5 is connected to the high speed test channel board interface, the FPGA code config generator 6, the high speed test channel driver FPGA 7 capable of configuring an interface protocol, the high speed test channel unit 8, and the configurable test data processor 9 respectively; the high speed test channel driver FPGA 7 capable of configuring an interface protocol is connected to the FPGA code config generator 6, the high speed test channel unit 8, and the configurable test data processor 9 respectively; and

The bus interface 11 configured for data transmission and control between the test processor board interface 5, the FPGA code configuration generator 6, the high speed test channel driver FPGA 7 capable of configuring an interface protocol, the high speed test channel unit 8, and the configurable test data processor 9.

The test processor board interface 5 is connected to the high speed test channel board interface of the mid speed test channel unit 3 to receive control and synchronization signals of the test processor 2.

The FPGA code configuration generator (FCCG) 6 is configured to: receive PC data and complete reconfiguration of the high speed test channel driver FPGA 7 capable of configuring an interface protocol. PC software may pre-configure a series of corresponding driver protocol FPGA RTL codes for various high speed digital interfaces. Testing engineers only need to select the corresponding protocol codes for configuration and download according to testing requirements to achieve test program development for various high speed digital interfaces. For example, if a high speed test channel driver (HSTCD) is required to drive a high speed test channel to output a MIPI D-Phy protocol signal, the PC downloads data of the MIPI D-Phy protocol for the FCCG, and the FCCG then configures the HSTCD, so that the HSTCD may become a test channel control generator of the MIPI D-Phy protocol.

The high speed test channel driver FPGA 7 capable of configuring an interface protocol (HSTCD) may be reconfigured by the FCCG, so as to have the universal driving capabilities for various high speed interface protocols. The high speed test channel driver FPGA 7 capable of configuring an interface protocol is configured to directly control a high speed test channel (HSTC), so the HSTC can output or match high speed test signals (from hundreds of Mbps to several Gbps).

The high speed test channel unit 8 includes one or more high speed test channels (HSTC), and each high speed test channel is composed of a high speed electronic pin (HSEP, composed of a PPMU, a driver, a comparator, and the like, to complete direct current testing of a DUT, perform input/output level conversion, and the like), and a multiplexer Mux.

The configurable test data processor 9 (CTDP) is composed of a data memory and a data processor. The configurable test data processor performs real-time calculation on test data obtained by the high speed test channel driver FPGA 7 capable of configuring an interface protocol, and synchronizes a test result to the test processor. The data processor is composed of a multi-core Arm, and a processing program run on the data processor can be downloaded and configured in real-time by the PC. Testing engineers can write a data processing program using ATE software and download it to the CTDP along with a test program.

The high speed digital test channel board 10 (HSDTCB) is configured to: complete generation and testing of test signals for high speed digital interfaces on a DUT, and complete real-time data processing and analysis.

The test processor board interface 5 is connected to the high speed test channel board interface of the mid speed test channel unit 3, so that the mid speed digital test channel board 4 and the high speed digital test channel board 10 form a mother and son board relationship. Outputs of various test channels of the mid speed digital test channel board 4 and outputs of various test channels of the high speed digital test channel board 10 are connected through their respective multiplexers Mux. According to the testing requirements, the test processor 2 performs switching between the outputs of the high speed test channels and the outputs of the mid speed test channels and provides the outputs to the DUT, thereby completing mid speed and high speed matched universal testing.

The high speed digital test channel board 10 includes a group of high speed digital test channel which is in one-to-one correspondence to the mid speed test channel group of the mid speed digital test channel board 4. Considering that the cost of the test channels on the high speed digital test channel board 10 is greater than that of the test channels on mid speed digital test channel board 4, in an actual testing scheme, a corresponding number of high speed digital test channel boards can be selected and mounted on the mid speed digital test channel board 4 according to a test channel requirement of the high speed digital interfaces on the DUT. This can maximize the testing performance, reduce the testing costs, and achieve the optimal cost-effectiveness.

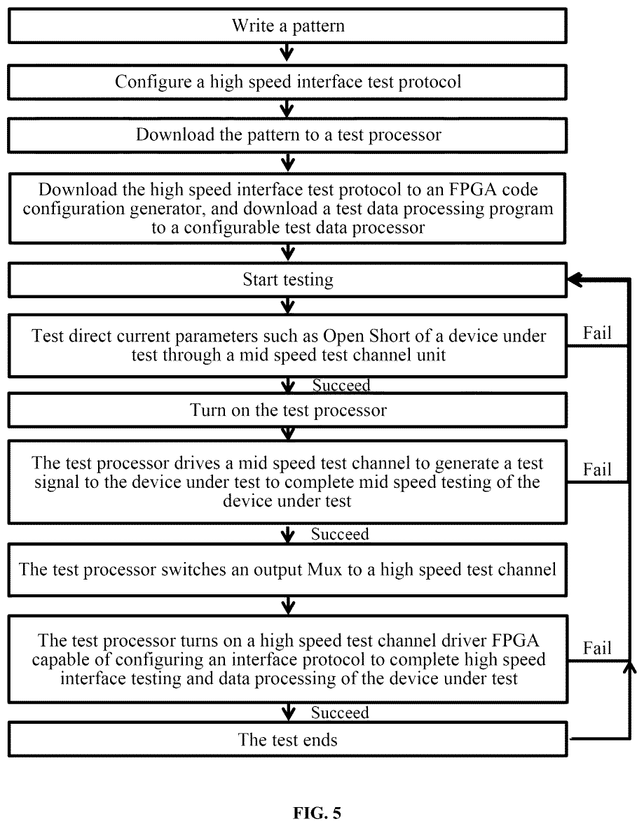

A universal detection method for a high speed digital interface of an integrated circuit, as shown in FIG. 5, includes the following steps:

step 1, writing a pattern, and configuring a high speed interface test protocol in integrated circuit ATE software;

step 2, downloading the pattern to the test processor 2;

step 3, downloading the high speed interface test protocol to the FPGA code config generator 6, and downloading a test data processing program to the configurable test data processor 9;

step 4, starting testing;

step 5, testing a direct current parameter, such as Open Short, of a device under test through the mid speed test channel unit 3; if the testing fails, executing step 4; and if the testing succeeds, turning on the test processor 2;

step 6, driving, by the test processor 2, a mid speed test channel in the mid speed test channel unit 3 to generate a test signal to the device under test, thus completing mid speed testing of the device under test; if the testing fails, executing step 4; and if the testing succeeds, switching, by the test processor 2, the multiplexer Mux to the high speed test channel unit 8;

step 7, turning on, by the test processor 2, the high speed test channel driver FPGA 7 capable of configuring an interface protocol to cause the high speed test channel unit 8 to generate a test signal to the device under test, thus completing high speed interface testing and data processing of the device under test; The configurable test data processor 9 performs real-time calculation on test data obtained by the high speed test channel driver FPGA 7 capable of configuring an interface protocol, and synchronizes a test result to the test processor 2. if the testing fails, executing step 4; and if the testing succeeds, ending the testing.

This embodiment adds a high speed digital test channel board on a mid speed test channel board, which can simultaneously complete testing of a mid speed IO and a high speed digital interface of a DUT.

The foregoing descriptions are preferable implementations of the present disclosure only. It is noted that a person of ordinary skill in the art may make some improvements and modifications without departing from the principle of the present disclosure and the improvements and modifications shall fall within the protection scope of the present disclosure.

What is claimed is:

1. A universal detection device for a high speed digital interface of an integrated circuit, comprising a mid speed digital test channel board (4) and a high speed digital test channel board (10), wherein
the mid speed digital test channel board (4) comprises a bus interface (1), a test processor (2), and a mid speed test channel unit (3); the bus interface (1) is connected to the test processor (2) and the mid speed test channel unit (3); the test processor (2) is connected to the mid speed test channel unit (3); the mid speed test channel unit (3) comprises one or more groups of mid speed test channel groups; and a high speed test channel board interface is arranged on each group of mid speed test channel group;
the high speed digital test channel board (10) comprises a bus interface (11), a test processor board interface (5), a field programmable gate array (FPGA) code config generator (6), a high speed test channel driver FPGA (7) capable of configuring an interface protocol, a high speed test channel unit (8), and a configurable test data processor (9); the FPGA code config generator (6) is configured to receive upper computer data to complete reconfiguration of the high speed test channel driver FPGA (7) capable of configuring an interface protocol;
the high speed test channel driver FPGA (7) capable of configuring an interface protocol is configured to directly control the high speed test channel unit (8); the bus interface (11) is connected to the FPGA code config generator (6), the high speed test channel driver FPGA (7) capable of configuring an interface protocol, the high speed test channel unit (8), and the configurable test data processor (9) respectively; the test processor board interface (5) is connected to the high speed test channel board interface, the FPGA code config generator (6), the high speed test channel driver FPGA (7) capable of configuring an interface protocol, the high speed test channel unit (8), and the configurable test data processor (9) respectively; the high speed test channel driver FPGA (7) capable of configuring an interface protocol is connected to the FPGA code config generator (6), the high speed test channel unit (8), and the configurable test data processor (9) respectively; and the test processor board interface (5) is connected to a high speed test channel board interface of the mid speed test channel unit (3) to receive control and synchronization signals of the test processor (2).

2. The universal detection device for the high speed digital interface of the integrated circuit according to claim 1, wherein the test processor (2) is configured to execute a pattern to generate a timing signal required by testing and a control signal required by a test channel, and provide the timing signal required by testing and the control signal required by a test channel to the mid speed test channel unit (3), and is configured to generate a control signal required by the high speed digital test channel board (10) to synchronize each high speed test channel driver FPGA (7) capable of configuring an interface protocol on the high speed test channel unit (8) with the test data processor.

3. The universal detection device for the high speed digital interface of the integrated circuit according to claim 2, wherein the mid speed test channel group comprises c pin, an input/output level converter, and a group of multiplexers; the electronic pin is configured to complete direct current testing of a device under test; the input/output level converter is configured to convert an input level and an output level; and the multiplexers are configured to output multiplexing signals.

4. The universal detection device for the high speed digital interface of the integrated circuit according to claim 3, wherein the high speed test channel unit (8) comprises one or more high speed test channels.

5. The universal detection device for the high speed digital interface of the integrated circuit according to claim 4, wherein the high speed test channels and the mid speed test channel groups are in one-to-one correspondence.

6. A detection method based on the universal detection device for the high speed digital interface of the integrated circuit according to claim 1, comprising the following steps:
step 1, writing a pattern, and configuring a high speed interface test protocol in integrated circuit ATE software;
step 2, downloading the pattern to the test processor (2);
step 3, downloading the high speed interface test protocol to the FPGA code config generator (6), and downloading a test data processing program to the configurable test data processor (9);
step 4, starting testing;
step 5, testing a direct current parameter of a device under test through the mid speed test channel unit (3); if the testing fails, executing step 4; if the testing succeeds, turning on the test processor (2);
step 6, driving, by the test processor (2), a mid speed test channel in the mid speed test channel unit (3) to generate a test signal to the device under test, thus completing mid speed testing of the device under test; if the testing fails, executing step (4); if the testing succeeds, switching, by the test processor (2), the multiplexer to the high speed test channel unit (8);
step 7, turning on, by the test processor (2), the high speed test channel driver FPGA (7) capable of configuring an interface protocol to cause the high speed test channel unit (8) to generate a test signal to the device under test, thus completing high speed interface testing and data processing of the device under test; if the testing fails, executing step 4; and if the testing succeeds, ending the testing.

7. The detection method according to claim 6, wherein the configurable test data processor (9) performs real-time calculation on test data obtained by the high speed test channel driver FPGA (7) capable of configuring an interface protocol, and synchronizes a test result to the test processor (2).
